(19) United States
(12) Patent Application Publication
(10) Pub. No.: US 2020/0096869 A1
(43) Pub. Date: Mar. 26, 2020

(54) Ultra-High Resolution Conductive Traces Flexible Biocomposites by Resist Stenciling

(71) Applicant: Georgia Tech Research Corporation, Atlanta, GA (US)

(72) Inventors: Ruilong Ma, Atlanta, GA (US); Vladimirv V. Tsukruk, Atlanta, GA (US)

(21) Appl. No.: 16/505,212

(22) Filed: Jul. 8, 2019

Related U.S. Application Data
(60) Provisional application No. 62/696,366, filed on Jul. 11, 2018.

(51) Int. Cl. G03F 7/26; G03F 7/20; D21H 13/34; D21H 17/67; D21H 25/02

(52) U.S. Cl. CPC G03F 7/265; G03F 7/2016; C01B 32/198; D21H 17/675; D21H 25/02; D21H 13/34

(57) ABSTRACT

In a method of making a conductive structure, a reducing agent is applied to a region of a sheet of graphene oxide composite paper for a predetermined amount of time. The reducing agent is removed after the predetermined amount of time so as to expose a region of reduced graphene oxide disposed in the sheet of graphene oxide composite paper. A conductive structure includes a sheet of graphene oxide composite paper. At least one region on the sheet of graphene oxide composite paper includes reduced graphene oxide.

### CROSS-REFERENCE TO RELATED APPLICATION(S)

This application claims the benefit of U.S. Provisional Patent Application Ser. No. 62/696,366, filed Jul. 11, 2018, the entirety of which is hereby incorporated herein by reference.

### STATEMENT OF GOVERNMENT SUPPORT

This invention was made with government support under grant number FA9550-17-1-0297, awarded by the Department of Defense; and grant number FA9550-14-1-0269, awarded by the Department of Defense; and grant number 1538215, awarded by the National Science Foundation. The government has certain rights in the invention.

### BACKGROUND OF THE INVENTION

### 1. Field of the Invention

The present invention relates to methods of making conductive traces and, more specifically, to methods of making conductive traces on graphene oxide composite paper.

### 2. Description of the Related Art

The world is seeing a proliferation of distributed networks of miniaturized sensors and computers. Connecting and powering these ubiquitous devices presents new challenges not met by current fabrication technologies. For instance, devices interfaced on clothing, on skin, or in the human body need to be soft and flexible, while conventional electronics are hard and rigid, unable to maintain performance to accommodate bending arising from bodily motion. Additionally, renewable and readily-available sources of energy (including light, wind, wasted energy in body motion, mechanical vibrations, and heat) cannot provide constant power, and are also distributed in nature. One promising avenue is the development next-generation energy-storage devices that are flexible to accommodate diverse use scenarios; and sufficiently small and low-cost to be ubiquitously placed to connect energy harvesters with sensing and computational components.

Graphene oxide (GO) is a prospective candidate material for flexible conductors and energy storage. GO can be exfoliated from earth-abundant graphite using solution-scalable methods, and can adopt a wide gamut of mechanical and electronic properties via its reduction or surface modification. The structure of GO consists of a monolayer hexagonal network of sp² hybridized carbon interspersed with sp³ carbon bearing oxygen-containing functional groups, with hydroxyl and epoxy groups at the basal plane, and carboxy and carbonyl groups at sheet edges. The removal of these oxygenated groups via reduction processes can produce an increase in conductivity by several orders of magnitude (up to 10⁴ S/m in graphene oxide-silk fibroin, GO-SF, composites), opening a route toward applications in flexible energy storage. There is interest in the assembly of nanocomposites, whereby GO acts as 2D ‘bricks’ bound by 1D polymeric binders to yield nacre-like structures designed for superior mechanical properties, including extreme tensile strength (526.7 MPa in GO-chitosan), Young's modulus, toughness (13.9 MJ/m³ reduced graphene oxide-silk fibroin, GO-SF), and stretchability (up to 10.1% in GO-polyvinyl alcohol). Synergistic effects arise from confined networks of intermolecular interactions to produce materials with superior mechanical properties in composites otherwise comprised of soft constituent components. However, the investigation of layered graphene composites has been largely confined to structural applications, and only a few publications explored multifunctional applications or applications in microelectronic components.

Exploration into introducing electrical conductivity into GO via reduction reactions began in earnest in the last decade, and have yielded a plethora of chemical and physical methods. Chemical methods include reduction of GO by diverse reductants such hydrazine, melamine, anodic metals, ascorbic acid; while physical methods include reduction by thermal annealing, electrochemistry, microwave pulse, and light irradiation. However, there has been considerable focus on the indiscriminate, areal reduction of GO. These methods generally do not localize the generation of conductive reduced GO features within the critical dimensions required by modern microelectronics, with current generation package substrates approaching sub-10-μm line width/space, and image pixels of camera phones at 1.5 μm.

High resolution, patterned reduction of graphene oxide on the single-micron length scale have been reported using strategies such as laser scribing, ion beam conversion, or contact by hot probe. While these techniques can achieve reduced GO features with critical dimensions of approaching 100-μm for laser scribing, 20-nm for ion beam, and 12-nm for hot probe, ultimately, they are based on serial techniques that generally cannot scale for high-volume manufacturing across wafer-and panel-sized substrates.

Therefore, there is a need for flexible conductive structure.

### SUMMARY OF THE INVENTION

The disadvantages of the prior art are overcome by the present invention which, in one aspect, is a method of making a conductive structure, in which a reducing agent is applied to a region of a sheet of graphene oxide composite paper for a predetermined amount of time. The reducing agent is removed after the predetermined amount of time so as to expose a region of reduced graphene oxide disposed in the sheet of graphene oxide composite paper.

In another aspect, the invention is a method of making a conductive trace on a paper, in which a layer of a photoresist is applied to a sheet of graphene oxide/silk composite paper. A photo mask is placed on the layer of photoresist. The photo mask includes at least one opaque region and defines at least one transparent region. The photo mask is exposed to photoresist-activating light so as to harden the photoresist in a region below the at least one transparent region. Any uncured photoresist is removed from the sheet of graphene oxide/silk composite paper, thereby exposing graphene oxide in the region below the at least one opaque region. A reducing agent is applied to the region in which graphene oxide is exposed and to the cured photoresist for a predetermined amount of time. The reducing agent is removed after the predetermined amount of time so as to expose a region of reduced graphene oxide disposed in the sheet of graphene oxide/silk composite paper.

In yet another aspect, the invention is a conductive structure that includes a sheet of graphene oxide composite paper. At least one region on the sheet of graphene oxide composite paper includes reduced graphene oxide.

These and other aspects of the invention will become apparent from the following description of the preferred embodiments taken in conjunction with the following drawings. As would be obvious to one skilled in the art, many variations and modifications of the invention may be effected without departing from the spirit and scope of the novel concepts of the disclosure.

### BRIEF DESCRIPTION OF THE FIGURES OF THE DRAWINGS

FIGS. 1A-1E are a cross-sections schematic diagrams demonstrating one method of making conductive traces of a graphene-oxide/silk fibril composite paper.

FIG. 2A is a micrograph of an initial photomask.

FIG. 2B is a micrograph of a resist with transferred mask pattern on a graphene-oxide/silk fibril composite paper.

FIG. 2C is a micrograph of a deposition of aluminum reductant.

FIG. 2D is a micrographs of a conductive feature patterned on a graphene-oxide/silk fibril composite paper after stripping the resist.

FIG. 3A is a schematic diagram showing a mask trace pattern for a super-capacitor.

FIG. 3B is a plan view a super-capacitor formed on a graphene-oxide/silk fibril composite paper.

FIG. 4A is a schematic diagram showing a mask trace pattern for an antenna element.

FIG. 4B is a plan view an antenna element formed on a graphene-oxide/silk fibril composite paper.

FIG. 5A is a schematic diagram showing a mask trace pattern for a grating.

FIG. 5B is a plan view a grating formed on a graphene-oxide/silk fibril composite paper.

### DETAILED DESCRIPTION OF THE INVENTION

A preferred embodiment of the invention is now described in detail. Referring to the drawings, like numbers indicate like parts throughout the views. Unless otherwise specifically indicated in the disclosure that follows, the drawings are not necessarily drawn to scale. The present disclosure should in no way be limited to the exemplary implementations and techniques illustrated in the drawings and described below. As used in the description herein and throughout the claims, the following terms take the meanings explicitly associated herein, unless the context clearly dictates otherwise: the meaning of “a,” “an,” and “the” includes plural reference, the meaning of “in” includes “in” and “on.”

Also, as used herein, “electron-beam deposition” means deposition employing a method such as “electron-beam physical vapor deposition.”

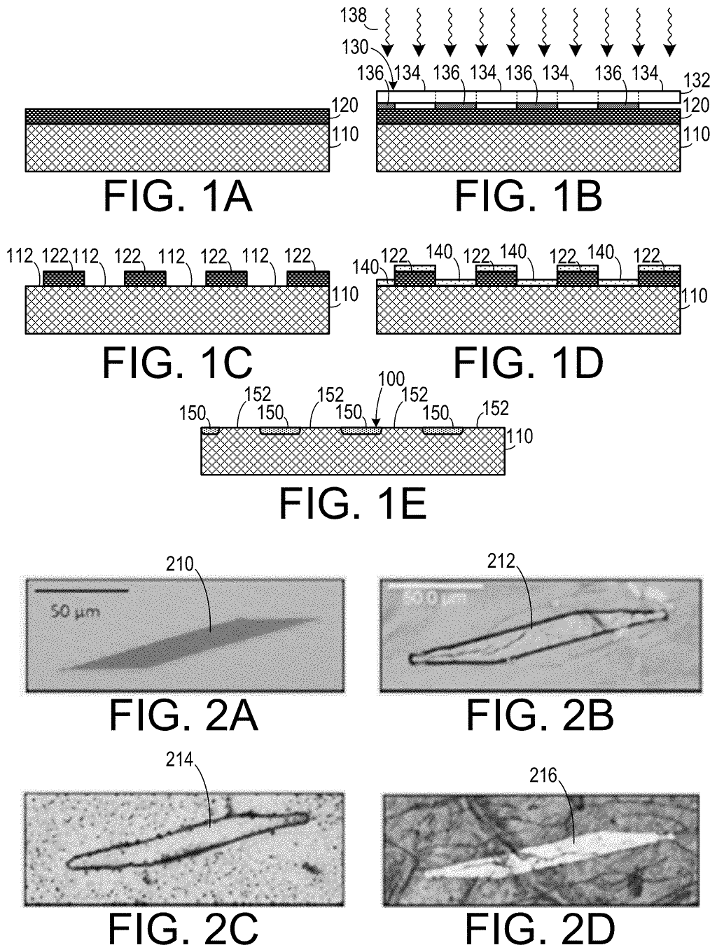

As shown in FIG. 1A, in one representative method of making a conductive structure, a layer of a photoresist 120 is applied to a sheet of graphene oxide-composite paper 110 (such as a composite paper made for graphene oxide particles—which can include flakes—and bio-protein fibers such as silk fibers). As shown in FIG. 1B, a photo mask 130 is placed on the photoresist layer 120. The photo mask 130 includes at least one opaque region 136 and defines at least one transparent region 134. The photo mask 130 is exposed to photoresist-activating light 138 so that cured photoresist 122 in the regions below the transparent region 134 cures and hardens. As shown in FIG. 1C, the uncured photoresist is removed from the sheet of graphene oxide composite paper 110, which graphene oxide in regions 112 between the cured photoresist regions 122. As shown in FIG. 1D, A reducing agent 140 is deposited to the regions 112 in which graphene oxide is exposed. (In one experimental embodiment, the reducing agent 140 includes aluminum applied using electron beam deposition. However, other reducing agents, such as copper, titanium, titanium nanoparticles and combinations thereof, may be used in certain embodiments.) The reducing agent 140 is allowed to remain for a predetermined amount of time and is then removed, as shown in FIG. 1E, thereby exposing regions of reduced graphene oxide 150, which have a substantially higher conductivity than the regions of non-reduced graphene oxide 152.

A micrograph of a region of exposed photoresist 210 on graphene oxide composite paper is shown in FIG. 2A, the developed region 212 is shown in FIG. 2B, the region 214 with aluminum deposited thereon is show in FIG. 2C and the resulting conductive region 216 is shown in FIG. 2D.

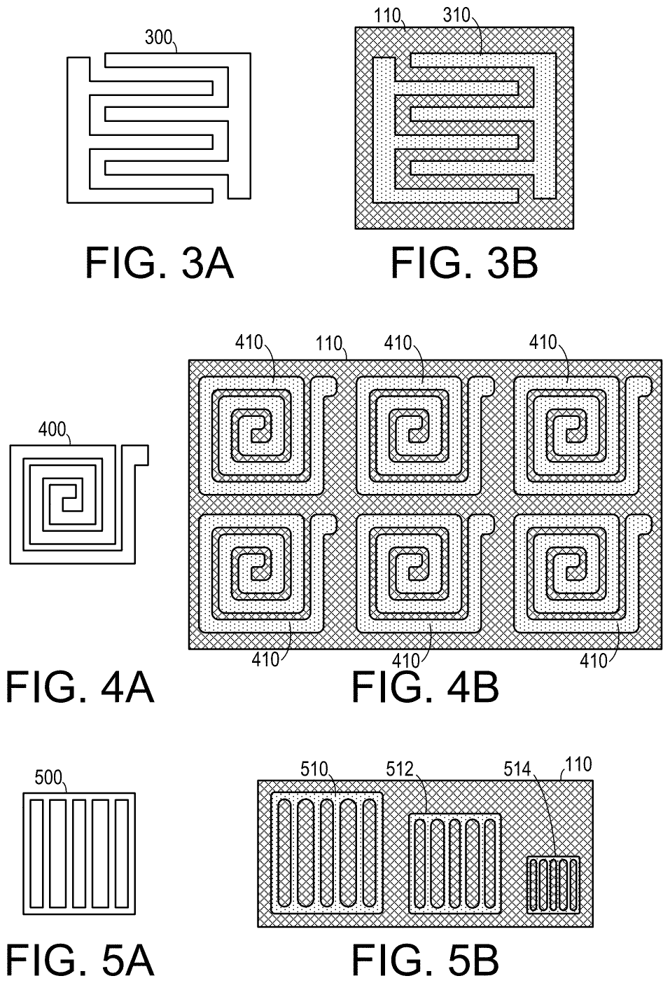

Using the above-described method, various electrical elements can be made on a sheet of graphene oxide composite paper. For example, as shown in FIGS. 3A and 3B, a mask stencil 300 with interleaving conductive fingers can be used to generate a capacitor 310 (of a type that can be used in many electrical and electronic applications) on the sheet of graphene oxide composite paper 110. As shown in FIGS. 4A and 4B, a mask stencil 400 with a spiral shape can be used to generate an antenna element 410 (of a type that could be used, for example, in MIMO communication system and phased array antenna systems) on the sheet of graphene oxide composite paper 110. As shown in FIGS. 5A and 5B, a mask stencil 500 with a grating shape can be used to generate a grating element 510 (of a type that could be used, for example, in interferometry) on the sheet of graphene oxide composite paper 110.

The graphene oxide-composite paper can be generated by making a slurry of fibers in a liquid (such as ultra-pure water) and adding graphene oxide particles or flakes to the slurry. Once mixed, the water can be removed from the slurry using a vacuum-type paper making system, which results in the graphene oxide composite paper.

One experimental embodiment includes a fabrication of flexible, micro-supercapacitors in a flexible, yet mechanically-robust, graphene oxide (GO) bionanocomposite paper through a resist-stenciling technique. This technique employs photolithography to generate a photoresist stencil, coupled with electron beam deposition to localize the placement of chemically-reduced features in the bionanocomposite at photolithographic length scales—demonstrating micro-structured reduced GO features with sub-micron critical dimensions (as small as 0.8-μm). The method can be generalized to enable the generation of micro-scale electrodes, antennae and interconnects in graphene oxide-based composites, opening a route to leverage the mechanical and electronic properties of GO and its derivative films.

In the experimental embodiment, a typical photolithography process is employed to generate a resist-based mask that protects selective loci of underlying graphene oxide-silk fiber (GO-SF) paper from contacting the reductant. Using electron-beam deposition, an anodic metal such as aluminum is deposited through the resist mask. The patterned resist acts as a conformal stencil to enable the transfer of the reduction pattern onto the underlying layered nanocomposite. GO-SF in contact with the aluminum undergoes controlled reduction. The E-beam deposition of other common deposited metals such as Cu and Ti can also induce reduction, though to a lesser extent than by Al in certain environments. Stripping the residual resist and washing the GO-SF biopaper lifts off the deposited Al and reveals reduced, conductive features written into the surface of the GO-SF biopaper.

The resist-stenciled method for patterned reduction described here is highly compatible with common photolithography processes. The conductive features can be generated using both representative positive and negative tone resist stencils respectively. Modifications were made to avoid baking at high temperatures, which could cause warpage of the GOSF biopaper due to mismatching coefficients of thermal expansion between layers and trapped moisture within the GO-SF. Reducing warpage ensured flat contact between the photomask and the resist-coated GO-SF to ensure optimal pattern transfer. The spin-coated resist helped make smooth inherent roughness on the surface of the GO-SF biopaper (Rq=52 nm). Conformal contact between the resist mask and the GO-SF biopaper means the resist stencil acts as a hard stop against the reducing agent contacting protected areas. Other scalable methods of patterned reduction may not be able ensure conformal contact. F or instance, in shadow masking flash lithography, separation between mask and GO-based substrate creates broad drop-off of reducing radiation intensity, while in stamping, asperities may block contact in surrounding loci to the reductant. While screen printing can create conformal contact between reductant and GO composite surface, the deposited reductant may deform due prior to and during firing to fix the reductant paste shape.

As discussed above with reference to FIGS. 2A-2D, regions of the biopaper that have undergone reduction change in visual appearance from the dull and brown characteristic of protected GO-SF biopaper to a grey and shiny appearance. FIGS. 2B-D shows optical micrographs illustrating the wide variety of accessible geometries of conductive features that can be formed by the patterned reduction process. Use of a common negative tone resist system resulted in conductive features in the GO-SF with line widths as small as 800 nm. This critical dimension of conductive features written into the biopapers was found to be defined by the dimensions of the resist stencil that is generated on top of the GO-SF biopaper. It is expected that the critical dimension of stencil features can be made even smaller with further optimization of process variables in the exposure, bake and development steps.

Besides change in visual appearance after guided reduction by resist stencil, it was determined through independent confirmation of chemical conversion by X-ray photoelectron spectroscopy (XPS) and Raman spectroscopy analyses that the C/O ratio increases in regions exposed by the resist stencil to 3.6±0.2, whereas protected regions retain the C/O ratio of 2.3±0.1 matching the C/O ratio of the as-prepared biopaper. This increase in the C/O ratio supports the partial removal of oxygen-containing moieties from the surface of GO-SF biopaper exposed by the resist stencil. The C1s spectra collected was deconvoluted into peaks centered around binding energies of 284.7, 286.5, and 288.5 eV; corresponding to carbon in the chemical states C—C, C—O, and C═O/O—C═O respectively. Deconvoluted spectra showed that the biopaper protected by the resist stencil has a significant fraction of surface carbon in higher binding energy chemical states, characteristic of carbon in oxygenated moieties represented in common models of GO. Surface carbon in the biopaper unprotected by the resist stencil shifts toward lower energy chemical states indicative of sp3 and sp2 carbon-carbon bonds.

The application of resist stencil-guided chemical reduction was used to fabricate integrated, nonflammable micro-supercapacitors into flexible GO-SF biopapers with enhanced mechanical robustness. Interdigitated electrode pairs were fabricated across the surface of GO-SF biopapers, as small as 9*10⁻⁴ mm² in footprint area, and having 2-um interdigitated finger width and gap separation. While pristine GO on its own has properties that promote energy storage such as high specific surface area and surface moieties that promote pseudo-capacitive faradaic reactions, its performance as an active material is limited by low electrical conductivity due to the presence of oxygenated moieties that disrupt the sp² basal plane. While the presence of interspersed SF in GO-SF biopapers promotes GO flake spacing, it further lowers the conductivity to ˜1×10⁻² S/m. On the other hand, metal-assisted reduction increases electrical conductivity of GO-SF by over 6 orders of magnitude up to 1.5×10⁻² S/m.

As a control, Pt wires secured with a spacing of 2.4 mm by micromanipulators across protected GO-SF show negligible integrated area and capacitance by CV testing. Resist stenciling enables the rational placement of micro-structured reduced GO-SF features as interdigitated fingers and busbars to facilitate charge collection, and electric double layer formation across the large area at the patterned electrode surface and edges. One embodiment resulted in the fabrication of interdigitated microelectrodes with as small as 2-μm fingers, and 9*10⁻⁴ mm² footprint.

Solid state micro -double layer capacitors (EDLCs) were fabricated by swelling the produced and patterned GO-SF paper in an aqueous 6M KOH solution to induce ionic conductivity and effectively fabricate a silk gel electrolyte. Reduced portions of the paper serve as electrodes, while the electronically insulative portion in between the electrodes serves as a separator. Using cyclic voltammetry (CV), we investigate the charge storage behavior of the micro-patterned GO-SF.

EDLCs with a rather thick (400 μm width) busbars collecting current from interdigitated and still relatively thick (200 μm) width fingers, forming symmetric electrodes. The separator membrane portion was designed to exhibit serpentine shape and a relatively large width of 200 μm. (Note that “regular” commercial devices typically utilize thinner (7550 μm) electrodes and thinner (10-25 μm) separators to achieve higher power capabilities. However, the experimental embodiment used larger dimensions for simplicity sufficient for this proof-of-concept device fabrication.)

As a control, Pt wires secured with a spacing of 2.4 mm by micromanipulators across protected GO-SF show negligible integrated area and capacitance by CV testing. At a scan rate of 10 mV/s, the specific capacitance (Csp) of fabricated devices reaches ˜130 F/g, which is comparable with many reduced GO-based and activated carbon-based electrodes (up to ˜150 F/g in aqueous KOH-based gel electrolytes). Distortion from the perfect horizontal rectangular shape of an ideal EDLC CV might be expected due to large electrode and separator dimensions and the associated increased contribution of the electrolyte resistance as well as other factors.

In order to observe accelerated aging, cycle stability of the produced EDLC was tested at a relatively high maximum voltage of 1V (compared to 0.6V commonly used in certain studies to avoid decomposition of water, electrode drying and formation of micro gas bubbles that further reduce access of electrolyte to the inner electrode surface area.) The observed stability of micro-EDLCs fabricated in GO-SF was quite reasonable. One experimental device retained ˜88% after 2000 charge cycles, which is in-line with laboratory-fabricated EDLCs with gel electrolytes cycled in a similar voltage range. Yet, it is inferior to EDLCs based on regular aqueous electrolytes, cycled within a lower voltage window and commonly comprising excess of electrolyte, which may show similar capacity retention after over 100,000 cycles or more.

Micro-patterned GO-SF EDLCs also demonstrate high mechanical robustness. Whereas layered composites, such as pristine GO paper, show low wet strength and will swell and fall apart in aqueous solution—the SF binder preserves the integrity of the GO-SF biopapers in the electrolyte. This enables the micro-supercapacitors fabricated in GO-SF biopapers to undergo repeated 90° bending (bend radius as little as ˜1 mm) without tearing. CV profiles show that the GO-SF still preserve a large integrated area, retaining 82.2±7.1% of original capacitance after 10 bending cycles, and 77.0±8.9% capacitance after 20 bending cycles. It is believed that the decreased EDLC performance to arise form bending causing closure of pores on the surface of the reduced GO-SF microelectrodes, decreasing the total electrode surface and ability to support the electrical double layer. However, it may be noted that the capacitance retention is significantly higher for the second set and subsequent sets of bending. This presents a tradeoff whereby the capacitance retention during device operation can be tuned high at the expense of rated capacity by ‘priming’ the GO-SF micro-supercapacitors via pre-bending.

Methods: Specific methods used in experimental embodiments are discussed below.

Vacuum-assisted layer-by-layer assembly of GO-SF biopapers. Silk fiber (SF) binder was extracted from the cocoon of the Bombyx mori silkworm in accordance with protocols pioneered by Kaplan et. al. Briefly, B. mori cocoons were cut and boiled in 0.02 MHa2CO2 for 30 min, then washed 3 times with ultrapure (18.2 MΩ-cm) water to yield degummed silk fibers. Silk fibers were solubilized in 9.3 M LiBr (at 1:10 wt. ratio of silk fiber to LiBr solution) at 60° C. for 2 hours. The solubilized SF was dialyzed against water to yield an aqueous stock solution of SF in water at a concentration of 50 mg/ml. Graphene oxide (GO) flakes were exfoliated according to the method of Hummers' from natural graphite powder (325 mesh, Alfa Aesar, USA) and diluted by ultrapure water to 5 mg/ml. To the GO dispersion was stirred the SF suspension to yield 3% dry weight SF. The GO-SF was collected onto a membrane filter (Pall Versapor, acrylic copolymer, 0.2 μm pore size) via a vacuum filtration setup to yield GO-SF biopapers with a flat side (filter side), and a rough side (air side).

Fabricating of resist stencil to guide biopaper reduction. The rough side of the GO-SF biopaper was mounted against a glass slide by glue stick. A patterned photoresist layer acts as a stencil to protect regions again reduction. In a typical experiment, negative-tone NR9-1500py ((Futurrex, Frankling, N.J., USA) was diluted in cyclohexanone and spin-coated onto the GO-SF biopaper to yield a 500-nm layer. The resist was exposed to 365 nm UV through a chrome photomask (PhotoSciences Inc.) with computer-aided design of microelectrode arrays. The resist was soft-baked and post-exposure baked at reduced temperature (80° C.), as typical bake temperatures of 150° C. was found to cause warping in GO-SF biopaper. Resist was immersion-developed (3:1 RD6/water) to yield stencil pattern protecting regions of the GO-SF against subsequent metal-assisted reduction.

Generation of conductive micro-traces in GO-SF biopapers. Electrochemical reduction of exposed GO-SF was undertaken by using a metal-assisted reduction technique based on methods previously reported by our lab. A 500-nm thick layer of Al, an anodic metal, was deposited via E-beam deposition (Mark 50, CHA Industries) onto the resist-stenciled GO-SF biopaper. The Al-coated GO-SF was dampened with ultrapure water (18.2 MΩ-cm), and clamped between PFTE blocks to undergo reduction for 4-hr, generating a depth of reduction feature of 1.2 μm as determined in a previous work. The Al-coated GO-SF is agitated in acetone to strip the residual resist, and lifting off large regions of coated Al. Residual Al was removed by washing the GO-SF biopaper in 0.1M HCl, and ultrapure water to yield GO-SF biopapers with micro-patterned conductive regions in the negative pattern of the photomask.

Characterizing reduced features in GO-SF biopapers. Reduced features on GO-SF biopapers were imaged by optical microscopy using a Leica DM 4000, and by low-voltage cold field emission scanning electron microscopy (Hitachi SU8230). Verification of chemical reduction was done by X-ray photoelectron spectroscopy (Thermo Scientific K-alpha), and Raman spectroscopy (Alpha-WiTec Alpha 300R, 532-nm laser).

Fabricating and characterizing micro-supercapacitors integrated into GO-SF biopaper. Conductive features were fabricated in the shape of interdigitated electrode pairs using resist stenciling to guide the reduction of GO-SF biopaper. The reduction patterned biopaper was soaked in 6M KOH for 1-hr under vacuum to allow for intercalation of electrolyte. The electrode busbars were clamped against Pt wires and connected to a potentiostat (VersaSTAT 3, Princeton Applied Research) for CV characterization at different scan rates (10, 50, 100, 200, 500, and 1000 mV/s). Csp was evaluated by voltammetric charge divided by potential window, scan rate and mass of active material. Voltammetric charge was determined by sum of integrated area of anodic and cathodic sweeps. The mass of the reduced GO-SF active material was determined by expression: active material area×reduction depth×GO-SF density, where reduction depth is 1.16 μm, and reduced GO-SF density of 1.8 g/cm³.^{[10]} Cyclic bending/unbending was performed for patterned GO-SF within a hinge (bend angle 90°, bend radius ˜1 mm) at 100 mV/s.

Although specific advantages have been enumerated above, various embodiments may include some, none, or all of the enumerated advantages. Other technical advantages may become readily apparent to one of ordinary skill in the art after review of the following figures and description. It is understood that, although exemplary embodiments are illustrated in the figures and described below, the principles of the present disclosure may be implemented using any number of techniques, whether currently known or not. Modifications, additions, or omissions may be made to the systems, apparatuses, and methods described herein without departing from the scope of the invention. The components of the systems and apparatuses may be integrated or separated. The operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set. It is intended that the claims and claim elements recited below do not invoke 35 U.S.C. § 112(f) unless the words “means for” or “step for” are explicitly used in the particular claim. The above described embodiments, while including the preferred embodiment and the best mode of the invention known to the inventor at the time of filing, are given as illustrative examples only. It will be readily appreciated that many deviations may be made from the specific embodiments disclosed in this specification without departing from the spirit and scope of the invention. Accordingly, the scope of the invention is to be determined by the claims below rather than being limited to the specifically described embodiments above.

What is claimed is:

1. A method of making a conductive structure, comprising the steps of:
(a) applying a reducing agent to a region of a sheet of graphene oxide composite paper for a predetermined amount of time; and
(b) removing the reducing agent after the predetermined amount of time so as to expose a region of reduced graphene oxide disposed in the sheet of graphene oxide composite paper.

2. The method of claim 1, wherein the reducing agent comprises a reducing agent selected from a list of reducing agents consisting of: aluminum, copper, titanium, titanium nanoparticles and combinations thereof.

3. The method of claim 1, wherein the step of applying a reducing agent includes applying the reducing agent using electron-beam deposition.

4. The method of claim 1, wherein the step of applying a reducing agent comprises the steps of:
(a) applying a layer of a photoresist to the sheet of graphene oxide composite paper;
(b) placing a photo mask on the layer of photoresist, the photo mask including at least one opaque region and defining at least one transparent region;
(c) exposing the photo mask to photoresist-activating light so as to harden the photoresist in a region below the at least one transparent region;
(d) removing any uncured photoresist from the sheet of graphene oxide composite paper, thereby exposing graphene oxide in the region below the at least one opaque region,
wherein the step of applying the reducing agent comprises applying the reducing agent to the region in which graphene oxide is exposed and to the cured photoresist.

5. The method of claim 1, further comprising the step of generating the photo mask such that the transparent region is formed in a capacitor shape so that the region of reduced graphene oxide includes a capacitor element.

6. The method of claim 1, further comprising the step of generating the photo mask such that the transparent region is formed in an antenna shape so that the region of reduced graphene oxide includes an antenna element.

7. The method of claim 1, further comprising the step of generating the photo mask such that the transparent region is formed in a grating shape so that the region of reduced graphene oxide includes an antenna element.

8. The method of claim 1, further comprising the step of generating the graphene oxide-composite paper by performing the steps of:
(a) generating a slurry of fibers in a liquid;
(b) adding a predetermined amount of graphene oxide particles to the slurry;
(c) removing the liquid from the slurry so as to form the graphene oxide-composite paper.

9. The method of claim 8, wherein the fibers comprise a fibrous bio-protein.

10. The method of claim 9, fibrous bio-protein comprises silk.

11. A method of making a conductive trace on a paper, comprising the steps of:
(a) applying a layer of a photoresist to a sheet of graphene oxide/silk composite paper;
(b) placing a photo mask on the layer of photoresist, the photo mask including at least one opaque region and defining at least one transparent region;
(c) exposing the photo mask to photoresist-activating light so as to harden the photoresist in a region below the at least one transparent region;
(d) removing any uncured photoresist from the sheet of graphene oxide/silk composite paper, thereby exposing graphene oxide in the region below the at least one opaque region;
(e) applying a reducing agent to the region in which graphene oxide is exposed and to the cured photoresist for a predetermined amount of time; and
(f) removing the reducing agent after the predetermined amount of time so as to expose a region of reduced graphene oxide disposed in the sheet of graphene oxide/silk composite paper.

12. The method of claim 11, wherein the reducing agent comprises a reducing agent selected from a list of reducing agents consisting of: aluminum, copper, titanium, titanium nanoparticles and combinations thereof.

13. The method of claim 11, further comprising the step of generating the photo mask such that the transparent region is formed in a capacitor shape so that the region of reduced graphene oxide is a capacitor element.

14. The method of claim 11, further comprising the step of generating the photo mask such that the transparent region is formed in an antenna shape so that the region of reduced graphene oxide is an antenna element.

15. The method of claim 11, further comprising the step of generating the photo mask such that the transparent region is formed in a grating shape so that the region of reduced graphene oxide is an antenna element.

16. The method of claim 11, further comprising the step of generating the graphene oxide/silk composite paper by performing the steps of:
(a) generating a slurry of silk fibers in a liquid;
(b) adding a predetermined amount of graphene oxide particles to the slurry;
(c) removing the liquid from the slurry so as to form the graphene oxide/silk composite paper.

17. A conductive structure, comprising:
(a) a sheet of graphene oxide composite paper;
(b) at least one region on the sheet of graphene oxide composite paper that includes reduced graphene oxide.

18. The conductive structure of claim 17, wherein the at least one region on the sheet of graphene oxide composite paper includes reduced graphene oxide disposed in a form of a capacitor element.

19. The conductive structure of claim 17, wherein the at least one region on the sheet of graphene oxide composite paper includes reduced graphene oxide disposed in a form of an antenna element.

20. The conductive structure of claim 17, wherein the at least one region on the sheet of graphene oxide composite paper that includes reduced graphene oxide disposed in a form of a grating element.

21. The conductive structure of claim 17, wherein the graphene oxide-composite paper comprises fibrous silk fibers and graphene oxide particles.
